(19) United States
(12) Patent Application Publication
(10) Pub. No.: US 2024/0006207 A1
(43) Pub. Date: Jan. 4, 2024

(54) BONDING APPARATUS AND BONDING METHOD

(71) Applicant: Tokyo Electron Limited, Tokyo (JP)

(72) Inventors: Takashi Nakamitsu, Koshi City (JP); Tetsuya Maki, Koshi City (JP); Yosuke Omori, Koshi City (JP); Keiichi Saiki, Koshi City (JP)

(21) Appl. No.: 18/341,903

(22) Filed: Jun. 27, 2023

(30) Foreign Application Priority Data
Jun. 29, 2022 (JP) 2022-104174
Feb. 17, 2023 (JP) 2023-023097

(51) Int. Cl. H01L 21/67; H01L 21/18; H01L 21/68; H01L 21/683

(52) U.S. Cl. CPC H01L 21/67259; H01L 21/67017; H01L 21/187; H01L 21/681; H01L 21/6838

(57) ABSTRACT

A bonding apparatus includes a first holder; a second holder; a horizontally moving unit; an elevating unit; an inclination measuring unit; and a controller. The first holder is configured to attract and hold a first substrate on a bottom surface thereof. The second holder is disposed under the first holder and configured to attract and hold a second substrate on a top surface thereof. The horizontally moving unit is configured to move the first substrate and the second substrate relative to each other in a horizontal direction. The elevating unit is configured to move the second substrate up and down between a proximate position and a spaced position. The inclination measuring unit is configured to measure an inclination of the second holder. The controller calculates a position of the second substrate in the horizontal direction based on a measurement result of the inclination measuring unit.

### CROSS-REFERENCE TO RELATED APPLICATION

This application claims the benefit of Japanese Patent Application Nos. 2022-104174 and 2023-023097 filed on Jun. 29, 2022 and Feb. 17, 2023, respectively, the entire disclosures of which are incorporated herein by reference.

### TECHNICAL FIELD

The various aspects and exemplary embodiments described herein pertain generally to a bonding apparatus and a bonding method.

### BACKGROUND

Conventionally, as a way to bond substrates such as semiconductor wafers, there is known a method in which bonding target surfaces of the substrates are modified, the modified surfaces of the substrates are hydrophilized, and the hydrophilized substrates are bonded by a Van der Waals force and a hydrogen bond (intermolecular force) (see, for example, Patent Document 1).
Patent Document 1: International Publication No. 2018/088094

### SUMMARY

In an exemplary embodiment, a bonding apparatus includes a first holder; a second holder; a horizontally moving unit; an elevating unit; an inclination measuring unit; and a controller. The first holder is configured to attract and hold a first substrate on a bottom surface thereof. The second holder is disposed under the first holder and configured to attract and hold, on a top surface thereof, a second substrate to be bonded to the first substrate. The horizontally moving unit is configured to move the first substrate and the second substrate relative to each other in a horizontal direction. The elevating unit is configured to move the second substrate up and down between a proximate position close to the first substrate and a spaced position farther from the first substrate than the proximate position. The inclination measuring unit is configured to measure an inclination of the second holder. The controller is configured to control the first holder, the second holder, the horizontally moving unit, the elevating unit and the inclination measuring unit. Further, the controller calculates a position of the second substrate in the horizontal direction based on a measurement result of the inclination measuring unit.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic plan view illustrating a configuration of a bonding system according to an exemplary embodiment;

FIG. 2 is a schematic side view illustrating the configuration of the bonding system according to the exemplary embodiment;

FIG. 3 is a schematic side view of an upper wafer and a lower wafer according to the exemplary embodiment;

FIG. 4 is a schematic cross-sectional view illustrating a configuration of a surface modifying apparatus according to the exemplary embodiment;

FIG. 5 is a schematic plan view illustrating a configuration of a bonding apparatus according to the exemplary embodiment;

FIG. 6 is a schematic plan view illustrating the configuration of the bonding apparatus according to the exemplary embodiment;

FIG. 7 is a schematic side view illustrating a configuration of an upper chuck and a lower chuck of the bonding apparatus according to the exemplary embodiment;

FIG. 8 is a flowchart illustrating a part of a processing sequence of a processing performed by the bonding system according to the exemplary embodiment;

FIG. 9 is a top view illustrating a configuration of a second holder according to the exemplary embodiment;

FIG. 10 is a side view illustrating a configuration of a first holder and the second holder according to the exemplary embodiment;

FIG. 11 is a diagram for describing a deviation amount calculating processing according to the exemplary embodiment;

FIG. 12 is a diagram for describing a sequence of an alignment processing according to the exemplary embodiment;

FIG. 13 is diagram for describing the sequence of the alignment processing according to the exemplary embodiment;

FIG. 14 is diagram for describing the sequence of the alignment processing according to the exemplary embodiment;

FIG. 15 is diagram for describing the sequence of the alignment processing according to the exemplary embodiment;

FIG. 16 is diagram for describing the sequence of the alignment processing according to the exemplary embodiment; and

FIG. 17 is diagram for describing the sequence of the alignment processing according to the exemplary embodiment.

### DETAILED DESCRIPTION

Hereinafter, exemplary embodiments of a bonding apparatus and a bonding method of the present disclosure will be described in detail with reference to the accompanying drawings. The present disclosure is not limited to the exemplary embodiments to be described below. Further, it should be noted that the drawings are schematic and relations in sizes of individual components and ratios of the individual components may sometimes be different from actual values. Even between the drawings, there may exist parts having different dimensional relationships or different ratios.

Conventionally, as a way to bond substrates such as semiconductor wafers, there is known a method in which bonding target surfaces of the substrates are modified, the modified surfaces of the substrates are hydrophilized, and the hydrophilized substrates are bonded by a Van der Waals force and a hydrogen bond (intermolecular force).

When forming a combined substrate by bonding the hydrophilized substrates, if the substrates are not precisely aligned, the precision of the bonding of the substrates is reduced. As a result, the yield of the combined substrate may be reduced.

Thus, there is a demand for a technology capable of improving the bonding precision between the substrates by overcoming the aforementioned problem.

<Configuration of Bonding System>

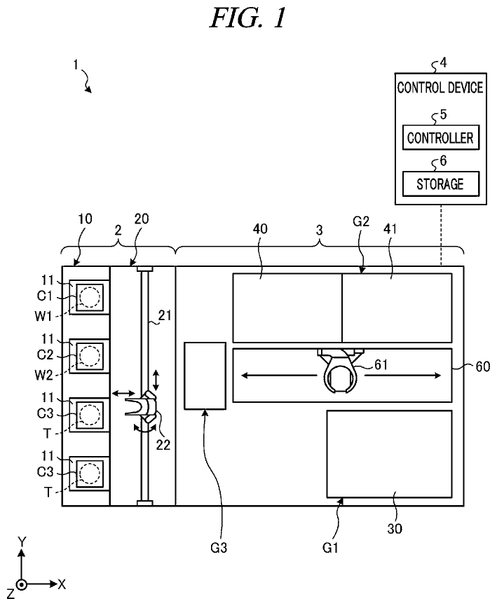

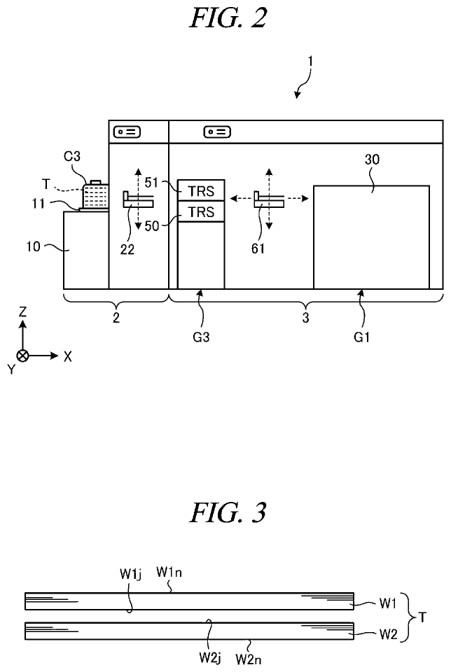

First, a configuration of a bonding system 1 according to an exemplary embodiment will be explained with reference to FIG. 1 to FIG. 3. FIG. 1 is a schematic plan view illustrating the configuration of the bonding system 1 according to the exemplary embodiment, and FIG. 2 is a schematic side view of the same. Further, FIG. 3 is a schematic side view of an upper wafer and a lower wafer according to the exemplary embodiment. In the various drawings referred to below, for the sake of easy understanding of the description, an orthogonal coordinate system in which the positive Z-axis direction is defined as a vertically upward direction may sometimes be used.

The bonding system 1 shown in FIG. 1 is configured to form a combined substrate T by bonding a first substrate W1 and a second substrate W2.

The first substrate W1 is a substrate on which a plurality of electronic circuits is formed on a semiconductor substrate such as a silicon wafer or a compound semiconductor wafer. The second substrate W2 is, for example, a bare wafer having no electronic circuit formed thereon. The first substrate W1 and the second substrate W2 have approximately the same diameter. Further, an electronic circuit may be formed on the second substrate W2.

Hereinafter, the first substrate W1 will be referred to as “upper wafer W1”, and the second substrate W2 will be referred to as “lower wafer W2”. That is, the upper wafer W1 is an example of a first substrate, and the lower wafer W2 is an example of a second substrate. Also, the upper wafer W1 and the lower wafer W2 together may be referred to as “wafer W”.

Further, in the following description, as shown in FIG. 3, among plate surfaces of the upper wafer W1, the plate surface to be bonded to the lower wafer W2 will be referred to as “bonding surface W1j”, and the plate surface opposite to the bonding surface W1j will be referred to as “non-bonding surface W1n”. Further, among plate surfaces of the lower wafer W2, the plate surface to be bonded to the upper wafer W1 will be referred to as “bonding surface W2j”, and the plate surface opposite to the bonding surface W2j will be referred to as “non-bonding surface W2n”.

As depicted in FIG. 1, the bonding system 1 is equipped with a carry-in/out station 2 and a processing station 3. The carry-in/out station 2 and the processing station 3 are arranged in the order of the carry-in/out station 2 and the processing station 3 along the positive X-axis direction. In addition, the carry-in/out station 2 and the processing station 3 are connected as one body.

The carry-in/out station 2 includes a placing table 10 and a transfer section 20. The placing table 10 is equipped with a plurality of placing plates 11. Cassettes C1, C2, and C3 each of which accommodates therein a plurality of (for example, 25 sheets of) substrates horizontally are respectively placed on the placing plates 11. For example, the cassette C1 accommodates therein the upper wafer W1; the cassette C2, the lower wafer W2; and the cassette C3, the combined substrate T.

The transfer section 20 is provided adjacent to the positive X-axis side of the placing table 10. Provided in this transfer section 20 are a transfer path 21 extending in the Y-axis direction and a transfer device 22 configured to be movable along this transfer path 21.

The transfer device 22 is configured to be movable in the X-axis direction as well as in the Y-axis direction and pivotable around the Z-axis. The transfer device 22 transfers the upper wafer W1, the lower wafer W2, and the combined substrate T between the cassettes C1 to C3 placed on the placing plates 11 and the processing station 3 to be described later.

Further, the number of the cassettes C1 to C3 disposed on the placing plates 11 is not limited to the shown example. In addition to the cassettes C1, C2, and C3, a cassette for collecting a defective substrate or the like may also be disposed on the placing plate 11.

The processing station 3 includes a plurality of processing blocks, for example, three processing blocks G1, G2 and G3, equipped with various types of apparatuses. By way of example, the first processing block G1 is provided on the front side (negative Y-axis side of FIG. 1) of the processing station 3, and the second processing block G2 is provided on the rear side (positive Y-axis side of FIG. 1) of the processing station 3. Further, the third processing block G3 is provided on the carry-in/out station 2 side (negative X-axis side in FIG. 1) of the processing station 3.

Disposed in the first processing block G1 is a surface modifying apparatus 30 configured to modify the bonding surface W1j of the upper wafer W1 and the bonding surface W2j of the lower wafer W2 with plasma of a processing gas. The surface modifying apparatus 30 cuts a SiO₂ bond on the bonding surfaces W1j and W2j of the upper wafer W1 and the lower wafer W2 into a single bond of SiO, thus allowing the bonding surfaces W1j and W2j to be modified so that they are easily hydrophilized afterwards.

Further, in the surface modifying apparatus 30, a preset processing gas is excited into plasma under, for example, a decompressed atmosphere to be ionized. As ions of an element contained in this processing gas are radiated to the bonding surfaces W1j and W2j of the upper wafer W1 and the lower wafer W2, the bonding surfaces W1j and W2j are modified by being plasma-processed. Details of this surface modifying apparatus 30 will be described later.

Disposed in the second processing block G2 is a surface hydrophilizing apparatus 40 and a bonding apparatus 41. The surface hydrophilizing apparatus 40 is configured to hydrophilize and clean the bonding surfaces W1j and W2j of the upper wafer W1 and the lower wafer W2 with, for example, pure water.

In the surface hydrophilizing apparatus 40, the pure water is supplied onto the upper wafer W1 or the lower wafer W2 while rotating the upper wafer W1 or the lower wafer W2 held by, for example, a spin chuck. Accordingly, the pure water supplied onto the upper wafer W1 or the lower wafer W2 is diffused on the bonding surface W1j of the upper wafer W1 or the bonding surface W2j of the lower wafer W2, so that the bonding surfaces W1j and W2j are hydrophilized.

The bonding apparatus 41 is configured to bond the upper wafer W1 and the lower wafer W2. Details of this bonding apparatus 41 will be described later.

In the third processing block G3, transition (TRS) devices 50 and 51 for the upper wafer W1, the lower wafer W2, and the combined substrate T are sequentially arranged in two levels from the bottom, as illustrated in FIG. 2.

Further, as shown in FIG. 1, a transfer section 60 is formed in an area surrounded by the first processing block G1, the second processing block G2, and the third processing block G3. In the transfer section 60, a transfer device 61 is disposed. The transfer device 61 has a transfer arm configured to be movable in a vertical direction and a horizontal direction and pivotable around a vertical axis, for example.

This transfer device 61 is moved within the transfer section 60 to transfer the upper wafer W1, the lower wafer W2, and the combined substrate T to preset apparatuses within the first processing block G1, the second processing block G2, and the third processing block G3 adjacent to the transfer section 60.

Furthermore, the bonding system 1 is equipped with a control device 4. The control device 4 controls an operation of the bonding system 1. The control device 4 is, for example, a computer, and includes a controller 5 and a storage 6. The storage 6 stores therein a program for controlling various kinds of processings such as a bonding processing. The controller 5 controls the operation of the bonding system 1 by reading and executing the program stored in the storage 6.

In addition, this program may be recorded on a computer-readable recording medium and installed from the recording medium to the storage 6 of the control device 4. The computer-readable recording medium may be, by way of non-limiting example, a hard disk (HD), a flexible disk (FD), a compact disk (CD), a magnet optical disk (MO), a memory card, or the like.

<Configuration of Surface Modifying Apparatus>

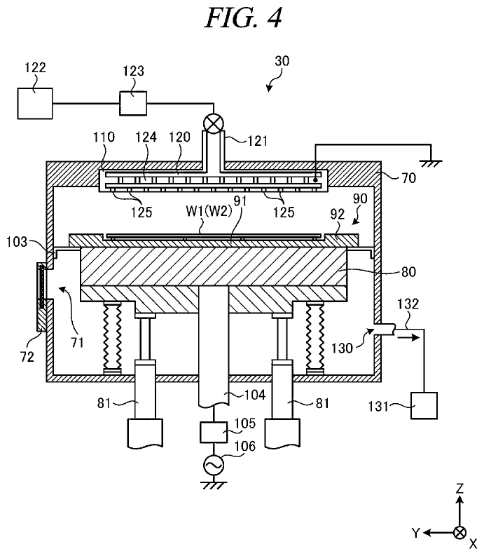

Now, a configuration of the surface modifying apparatus 30 will be explained with reference to FIG. 4. FIG. 4 is a schematic cross-sectional view illustrating the configuration of the surface modifying apparatus 30.

As depicted in FIG. 4, the surface modifying apparatus 30 includes a processing vessel 70 having a hermetically sealable inside. A carry-in/out opening 71 for the upper wafer W1 or the lower wafer W2 is formed at a side surface of the processing vessel 70 on the transfer section 60 (see FIG. 1) side, and a gate valve 72 is provided at the carry-in/out opening 71.

A stage 80 is disposed inside the processing vessel 70. The stage 80 serves as, for example, a lower electrode, and is made of a conductive material such as, but not limited to, aluminum. A plurality of driving units 81 equipped with, for example, a motor is provided under the stage 80. The driving units 81 are configured to move the stage 80 up and down.

An exhaust ring 103 provided with a multiple number of baffle holes is disposed between the stage 80 and an inner wall of the processing vessel 70. An atmosphere within the processing vessel 70 is uniformly exhausted from the inside of the processing vessel 70 through the exhaust ring 103.

A power feed rod 104 formed of a conductor is connected to a bottom surface of the stage 80. The power feed rod 104 is connected to a first high frequency power supply 106 via a matching device 105 which is composed of, for example, a blocking capacitor or the like. When a plasma processing is performed, a preset high frequency voltage is applied to the stage 80 from the first high frequency power supply 106.

An upper electrode 110 is disposed within the processing vessel 70. A top surface of the stage 80 and a bottom surface of the upper electrode 110 are disposed to face each other in parallel with a certain distance therebetween. The distance between the top surface of the stage 80 and the bottom surface of the upper electrode 110 is adjusted by the driving units 81.

The upper electrode 110 is grounded to be connected to the ground potential. Since the upper electrode 110 is grounded in this way, damage to the bottom surface of the upper electrode 110 can be suppressed during the plasma processing.

In this way, as the high frequency voltage is applied from the first high frequency power supply 106 to the stage 80 serving as the lower electrode, plasma is formed within the processing vessel 70.

In the exemplary embodiment, the stage 80, the power feed rod 104, the matching device 105, the first high frequency power supply 106 and the upper electrode 110 constitute an example of a plasma forming mechanism configured to form the plasma of the processing gas within the processing vessel 70. Moreover, the first high frequency power supply 106 is controlled by the controller 5 of the control device 4 described above.

A hollow space 120 is formed within the upper electrode 110. A gas supply line 121 is connected to this hollow space 120. The gas supply line 121 communicates with a gas source 122 that stores therein the processing gas or a gas for charge removal. Further, the gas supply line 121 is provided with a supply device group 123 including, for example, a flow rate controller and a valve configured to control a flow of the processing gas or the gas for charge removal.

Then, the processing gas or the gas for charge removal supplied from the gas source 122 is introduced into the hollow space 120 of the upper electrode 110 via the gas supply line 121 after its flow rate is adjusted by the supply device group 123. The processing gas may be, by way of example, an oxygen gas, a nitrogen gas, an argon gas, or the like. The gas for charge removal may be an inert gas such as, but not limited to, a nitrogen gas or an argon gas.

A baffle plate 124 is provided in the hollow space 120 to accelerate uniform diffusion of the processing gas or the gas for charge removal. The baffle plate 124 is provided with a number of small holes. A multiple number of gas discharge openings 125 are formed in the bottom surface of the upper electrode 110 to discharge the processing gas or the gas for charge removal from the hollow space 120 into the processing vessel 70.

The processing vessel 70 is provided with a suction port 130. Connected to the suction port 130 is a suction line 132 that communicates with a vacuum pump 131 configured to decompress the atmosphere within the processing vessel 70 to a certain degree of vacuum.

The top surface of the stage 80, that is, the surface facing the upper electrode 110 is a circular horizontal surface having a larger diameter than the upper wafer W1 and the lower wafer W2, when viewed from the top. A stage cover 90 is disposed on the top surface of the stage 80, and the upper wafer W1 or the lower wafer W2 is placed on a placing portion 91 of the stage cover 90.

<Configuration of Bonding Apparatus>

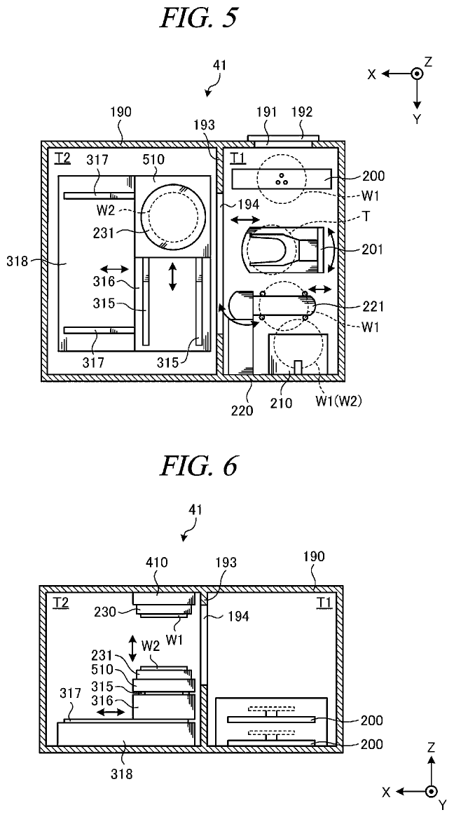

Now, a configuration of the bonding apparatus 41 will be discussed with reference to FIG. 5 and FIG. 6. FIG. 5 is a schematic plan view illustrating the configuration of the bonding apparatus 41 according to the exemplary embodiment, and FIG. 6 is a schematic side view illustrating the configuration of the bonding apparatus 41 according to the exemplary embodiment.

As depicted in FIG. 5, the bonding apparatus 41 has a processing vessel 190 having a hermetically sealable inside. A carry-in/out opening 191 for the upper wafer W1, the lower wafer W2, and the combined substrate T is formed at a side surface of the processing vessel 190 on the transfer section 60 side, and an opening/closing shutter 192 is provided at the carry-in/out opening 191.

The inside of the processing vessel 190 is partitioned into a transfer section T1 and a processing section T2 by an inner wall 193. The aforementioned carry-in/out opening 191 is formed at the side surface of the processing vessel 190 in the transfer section T1. Further, the inner wall 193 is also provided with a carry-in/out opening 194 for the upper wafer W1, the lower wafer W2, and the combined substrate T.

Further, the inside of the processing vessel 190 is maintained at a preset constant humidity by a non-illustrated humidity maintaining mechanism. Therefore, the bonding apparatus 41 is capable of performing a bonding processing of the upper wafer W1 and the lower wafer W2 in a stable environment.

On the negative Y-axis side of the transfer section T1, there is provided transition devices 200 each configured to temporarily place therein the upper wafer W1, the lower wafer W2, and the combined substrate T. The transition devices 200 are arranged in, for example, two levels, and are thus capable of placing therein any two of the upper wafer W1, the lower wafer W2, and the combined substrate T at the same time.

A transfer mechanism 201 is provided in the transfer section T1. The transfer mechanism 201 has a transfer arm configured to be movable in a vertical direction and a horizontal direction and pivotable around a vertical axis, for example. The transfer mechanism 201 transfers the upper wafer W1, the lower wafer W2, and the combined substrate T within the transfer section T1 or between the transfer section T1 and the processing section T2.

A position adjusting mechanism 210 configured to adjust the directions of the upper wafer W1 and the lower wafer W2 in a horizontal direction is provided on the positive Y-axis side of the transfer section T1. In this position adjusting mechanism 210, while rotating the upper wafer W1 and the lower wafer W2 attracted to and held by a non-illustrated holder, positions of notches of the upper wafer W1 and the lower wafer W2 are detected by a non-illustrated detector.

With this configuration, the position adjusting mechanism 210 adjusts the positions of the notches to thereby adjust the directions of the upper wafer W1 and the lower wafer W2 in the horizontal direction. Further, an inverting mechanism 220 configured to invert the front and rear surfaces of the upper wafer W1 is provided in the transfer section T1.

In addition, as illustrated in FIG. 6, an upper chuck 230 and a lower chuck 231 are provided in the processing section T2. The upper chuck 230 is configured to attract and hold the upper wafer W1 from above. The lower chuck 231 is disposed below the upper chuck 230, and is configured to attract and hold the lower wafer W2 from below.

The upper chuck 230 is supported by a base member 410 fixed to a ceiling surface of the processing vessel 190, as shown in FIG. 6. The upper chuck 230 and the base member 410 belong to a first holder 400 (see FIG. 10) that is configured to hold the upper wafer W1.

The base member 410 is equipped with a first imaging unit 430 (see FIG. 10) configured to image the bonding surface W2j of the lower wafer W2 held by the lower chuck 231. This first imaging unit 430 is disposed adjacent to, for example, the upper chuck 230.

Furthermore, as illustrated in FIG. 5 and FIG. 6, the lower chuck 231 is supported by a base member 510 provided below the lower chuck 231. The lower chuck 231 and the base member 510 belong to a second holder 500 (see FIG. 10) that is configured to hold the lower wafer W2.

The base member 510 is configured to be movable in a horizontal direction (Y-axis direction) and a vertical direction and pivotable around a vertical axis along with the lower chuck 231. The base member 510 is provided with a second imaging unit 530 (see FIG. 10) configured to image the bonding surface W1j of the upper wafer W1 held by the upper chuck 230. This second imaging unit 530 is disposed adjacent to, for example, the lower chuck 231.

Moreover, as shown in FIG. 5 and FIG. 6, the base member 510 is mounted to a pair of rails 315 elongated in the horizontal direction (Y-axis direction) with an elevating unit 520 to be described later therebetween. The base member 510 is configured to be movable along these rails 315.

The pair of rails 315 are provided on a horizontally moving unit 316. The horizontally moving unit 316 is mounted to a pair of rails 317, which is provided on the bottom surface side thereof and elongated in a horizontal direction (X-axis direction).

The horizontally moving unit 316 is configured to be movable along the rails 317, that is, to move the lower chuck 231 in the horizontal direction (X-axis direction). In addition, the pair of rails 317 are disposed on a placing table 318 provided on a bottom surface of the processing vessel 190.

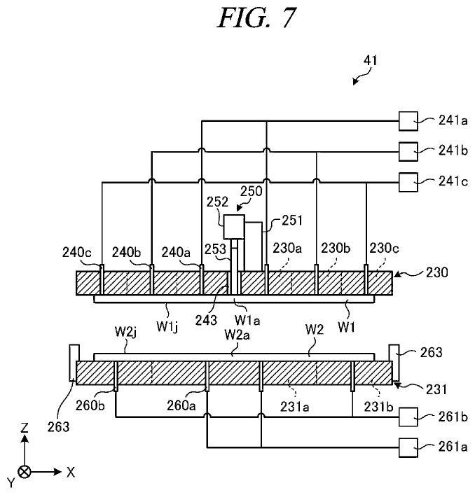

Now, a configuration of the upper chuck 230 and the lower chuck 231 in the bonding apparatus 41 will be described with reference to FIG. 7. FIG. 7 is a schematic side view illustrating the configuration of the upper chuck 230 and the lower chuck 231 of the bonding apparatus 41 according to the exemplary embodiment.

The upper chuck 230 is of a substantially circular plate shape, and is divided into a plurality of, for example, three regions 230a, 230b and 230c, as shown in FIG. 7. These regions 230a, 230b and 230c are arranged in this order from the center of the upper chuck 230 toward the periphery (edge) thereof. The region 230a has a circular shape when viewed from the top, and the regions 230b and 230c have an annular shape when viewed from the top.

Suction pipes 240a, 240b and 240c through which the upper wafer W1 is attracted and held are independently provided in the regions 230a, 230b and 230c, respectively, as depicted in FIG. 7. The suction pipes 240a, 240b and 240c are connected to separate vacuum pumps 241a, 241b and 241c, respectively. In this way, the upper chuck 230 is configured to set the vacuum-suction of the upper wafer W1 for each of the regions 230a, 230b and 230c.

A through hole 243 is formed through a central portion of the upper chuck 230 in a thickness direction thereof. The central portion of the upper chuck 230 corresponds to a central portion W1a of the upper wafer W1 attracted to and held by the upper chuck 230. A pressing pin 253 of a substrate pressing mechanism 250 is inserted through the through hole 243.

The substrate pressing mechanism 250 is provided on the top surface of the upper chuck 230, and serves to press the central portion W1a of the upper wafer W1 with the pressing pin 253. The pressing pin 253 is configured to be linearly movable along a vertical axis by a cylinder 251 and an actuator 252, and serves to press, with a leading end portion thereof, a substrate (the upper wafer W1 in the present exemplary embodiment) facing the leading end portion.

Specifically, when the upper wafer W1 and the lower wafer W2 are bonded as will be described later, the pressing pin 253 serves as a starter that first brings the center portion W1a of the upper wafer W1 and a center portion W2a of the lower wafer W2 into contact with each other.

The lower chuck 231 is of a substantially circular plate shape, and is divided into a plurality, for example, two regions 231a and 231b. These regions 231a and 231b are arranged in this order from the center of the lower chuck 231 toward the periphery thereof. Further, the region 231a has a circular shape when viewed from the top, whereas the region 231b has an annular shape when viewed from the top.

As shown in FIG. 7, suction pipes 260a and 260b through which the lower wafer W2 is attracted and held are independently provided in the regions 231a and 231b, respectively. The suction pipes 260a and 260b are connected to separate vacuum pumps 261a and 261b, respectively. In this way, the lower chuck 231 is configured to set the vacuum-suction of the lower wafer W2 for each of the regions 231a and 231b.

Stopper members 263 are provided at multiple positions, for example, five positions of the periphery of the lower chuck 231 to suppress the upper wafer W1, the lower wafer W2 and the combined substrate T from being protruded out of the lower chuck 231 or from being slid to fall off the lower chuck 231.

<Processing Performed by Bonding System>

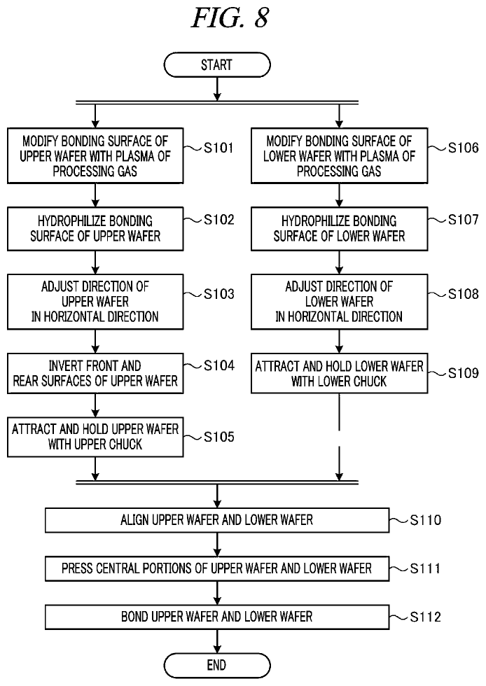

Now, referring to FIG. 8, details of a processing performed by the bonding system 1 according to the exemplary embodiment will be explained. Various processes described below are performed under the control of the controller 5 of the control device 4.

FIG. 8 is a flowchart illustrating a part of a processing sequence of the processing performed by the bonding system 1 according to the exemplary embodiment. First, the cassette C1 accommodating therein the upper wafers W, the cassette C2 accommodating therein the lower wafers W2, and the empty cassette C3 are placed on the placing plates 11 of the carry-in/out station 2.

Then, the upper wafer W1 within the cassette C1 is taken out by the transfer device 22, and transferred to the transition device 50 of the third processing block G3 of the processing station 3.

Next, the upper wafer W1 is transferred to the surface modifying apparatus of the first processing block G1 by the transfer device 61. At this time, the gate valve 72 is opened, and the inside of the processing vessel 70 is opened to the atmospheric pressure. In the surface modifying apparatus 30, the processing gas is excited into the plasma under the preset decompressed atmosphere to be ionized.

The ions thus generated are radiated to the bonding surface W1j of the upper wafer W1, so that the bonding surface W1j is plasma-processed. Accordingly, dangling bonds of silicon atoms are formed in the outermost surface of the bonding surface W1j, so that the bonding surface W1j of the upper wafer W1 is modified (process S101).

Subsequently, the upper wafer W1 is transferred to the surface hydrophilizing apparatus 40 of the second processing block G2 by the transfer device 61. In the surface hydrophilizing apparatus 40, while rotating the upper wafer W1 held by the spin chuck, pure water is supplied onto the upper wafer W1.

The supplied pure water is diffused on the bonding surface W1j of the upper wafer W1. As a result, in the surface modifying apparatus 30, OH groups (silanol groups) adhere to the dangling bonds of the silicon atoms in the bonding surface W1j of the modified upper wafer W1, so that the bonding surface W1j is hydrophilized (process S102). Further, the bonding surface W1j of the upper wafer W1 is cleaned by the pure water.

Next, the upper wafer W1 is transferred to the bonding apparatus 41 of the second processing block G2 by the transfer device 61. The upper wafer W1 carried into the bonding apparatus 41 is transferred to the position adjusting mechanism 210 via the transition device 200. The direction of the upper wafer W1 in the horizontal direction is adjusted by the position adjusting mechanism 210 (process S103).

Thereafter, the upper wafer W1 is delivered from the position adjusting mechanism 210 to the inverting mechanism 220. Then, in the transfer section T1, by operating the inverting mechanism 220, the front and rear surfaces of the upper wafer W1 are inverted (process S104). That is, the bonding surface W1j of the upper wafer W1 is turned to face down.

Then, the inverting mechanism 220 is rotated to be positioned below the upper chuck 230. Then, the upper wafer W1 is delivered from the inverting mechanism 220 onto the upper chuck 230. The non-bonding surface Win of the upper chuck W1 is attracted to and by the upper chuck 230 (process S105).

While the above-described processes S101 to S105 are being performed on the upper wafer W1, the lower wafer W2 is also processed. First, the lower wafer W2 within the cassette C2 is taken out by the transfer device 22, and transferred to the transition device 50 of the processing station 3.

Next, the lower wafer W2 is transferred to the surface modifying apparatus 30 by the transfer device 61, and the bonding surface W2j of the lower wafer W2 is modified (process S106). This process S106 is the same process as the above-described process S101.

Thereafter, the lower wafer W2 is transferred to the surface hydrophilizing apparatus 40 by the transfer device 61, and the bonding surface W2j of the lower wafer W2 is hydrophilized (process S107). This process S107 is the same process as the above-described process S102.

Then, the lower wafer W2 is transferred to the bonding apparatus 41 by the transfer device 61. The lower wafer W2 carried into the bonding apparatus 41 is transferred to the position adjusting mechanism 210 via the transition device 200. The direction of the lower wafer W2 in the horizontal direction is adjusted by the position adjusting mechanism 210 (process S108).

Thereafter, the lower wafer W2 is transferred to the lower chuck 231 to be attracted to and held by the lower chuck 231 (process S109). The non-bonding surface W2n of the lower chuck W2 is attracted to and held by the lower chuck 231 with the notch thereof directed toward the predetermined direction.

Next, alignment of the upper wafer W1 held by the upper chuck 230 and the lower wafer W2 held by the lower chuck 231 in the horizontal direction and the vertical direction is carried out (process S110). Details of this alignment processing will be described later.

At the end of the alignment processing, the distance between the bonding surface W2j of the lower wafer W2 and the bonding surface W1j of the upper wafer W1 is of a predetermined value, for example, 80 μm to 100 μm.

Next, by lowering the pressing pin 253 of the substrate pressing mechanism 250, the central portion W1a of the upper wafer W1 is pressed, allowing the central portion W1a of the upper wafer W1 and the central portion W2a of the lower wafer W2 to be pressed with a preset force (process S111).

Accordingly, the bonding between the pressed central portions W1a and W2a of the upper wafer W1 and the lower wafer W2 is started. Specifically, since the bonding surface W1j of the upper wafer W1 and the bonding surface W2j of the lower wafer W2 are modified in the processes S101 and S106, respectively, a van der Waals force (intermolecular force) is first generated between the bonding surfaces W1j and W2j, so that the bonding surfaces W1j and W2j are bonded to each other.

Further, since the bonding surface W1j of the upper wafer W1 and the bonding surface W2j of the lower wafer W2 are hydrophilized in the processes S102 and S107, respectively, the OH groups between the bonding surfaces W1j and W2j are hydrogen-bonded, so that the bonding surfaces W1j and W2j are firmly bonded to each other.

Afterwards, a bonding region between the upper wafer W1 and the lower wafer W2 expands from the central portions of the upper wafer W1 and the lower wafer W2 to the peripheries thereof. Thereafter, in the state that the central portion W1a of the upper wafer W1 and the central portion W2a of the lower wafer W2 are pressed with the pressing pin 253, the operation of the vacuum pump 241b is stopped, so that the vacuum-suction of the upper wafer W1 from the suction pipe 240b in the region 230b is stopped.

As a result, the upper wafer W1 held in the region 230b falls down onto the lower wafer W2. Then, the operation of the vacuum pump 241c is stopped to stop the vacuum-suction of the upper wafer W1 from the suction line 240c in the region 230c.

In this way, the vacuum-suction of the upper wafer W1 is stopped stepwise from the central portion W1a of the upper wafer W1 toward the periphery thereof, thus allowing the upper wafer W1 to be dropped onto the lower wafer W2 stepwise to be in contact with it. Then, the bonding between the above-described bonding surfaces W1j and W2j by the van der Waals force and the hydrogen bond spreads from the central portions W1a and W2a toward the peripheries gradually.

In this way, the entire bonding surface W1j of the upper wafer W1 and the entire bonding surface W2j of the lower wafer W2 come into contact with each other, so that the upper wafer W1 and the lower wafer W2 are bonded (process S112).

Thereafter, the pressing pin 253 is raised up to the upper chuck 230. Further, in the lower chuck 231, the vacuum-suction of the lower wafer W2 from the suction pipes 260a and 260b is stopped to release the attracting and holding of the lower wafer W2 by the lower chuck 231. Accordingly, the bonding processing in the bonding apparatus 41 is ended.

<Details of Alignment Processing>

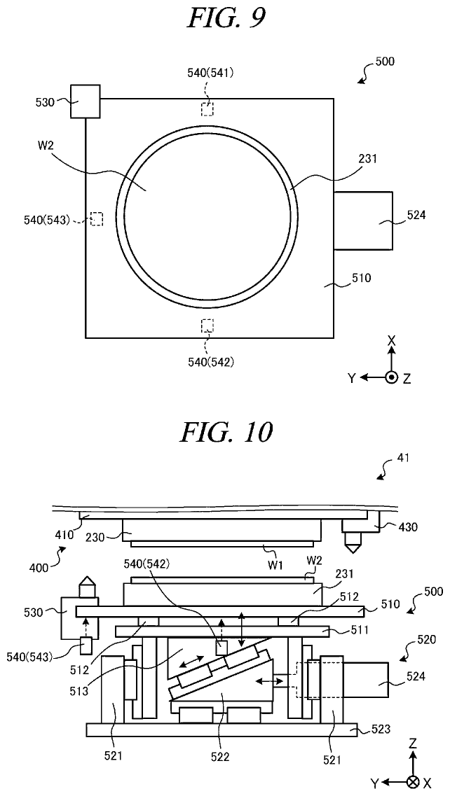

Now, details of the alignment processing for the upper wafer W1 and the lower wafer W2 performed in the bonding apparatus 41 according to the exemplary embodiment will be explained with reference to FIG. 9 to FIG. 17. FIG. 9 is a top view illustrating a configuration of the second holder 500 according to the exemplary embodiment, and FIG. 10 is a side view illustrating the configuration of the first holder 400 and the second holder 500 according to the exemplary embodiment.

As depicted in FIG. 10, the first holder 400 attracts and holds the upper wafer W1 on a bottom surface thereof. The first holder 400 has an upper chuck 230 and the base member 410. The first imaging unit 430 is provided at the base member 410.

The first imaging unit 430 is provided adjacent to, for example, the upper chuck 230, and images the bonding surface W2j (see FIG. 3) of the lower wafer W2 held by the lower chuck 231. The first imaging unit 430 is provided with a macro-camera (not shown) having a low image magnification and a wide field of view and a micro-camera (not shown) having a high image magnification and a narrow field of view.

The second holder 500 attracts and holds the lower wafer W2 on a top surface thereof. The second holder 500 has the lower chuck 231, the base member 510, a ceiling plate 511, a plurality of supports 512, and an inclined member 513.

The base member 510 is made of, for example, a plate-shaped metal member, and the lower chuck 231 is supported on a top surface thereof. The ceiling plate 511 is made of, for example, a plate-shaped metal member and is disposed below the base member 510.

The plurality of supports 512 are made of, for example, a metal member, and are disposed between the base member 510 and the ceiling plate 511. That is, the base member 510 is supported by the ceiling plate 511 with the plurality of supports 512 therebetween.

The inclined member 513 is provided on a bottom surface of the ceiling plate 511, and has an inclined surface at a lower portion thereof. An engagement member that is engaged with a rail below is arranged on this inclined surface.

An elevating unit 520 configured to move the second holder 500 up and down is provided below the second holder 500 described so far. The elevating unit 520 has a plurality of supports 521, an inclined member 522, a base member 523, and a moving unit 524.

The supports 521 support the ceiling plate 511 in such a manner that the ceiling plate 511 can be moved up and down. The supports 521 include, by way of example, a rail, which extends in a vertical direction and is operated integrally with the ceiling plate 511; and an engagement member engaged with the rail and fixed to the base member 523.

The inclined member 522 is disposed above the base member 523, and has an inclined surface at an upper portion thereof and a rail on a bottom surface thereof. The inclined surface of the inclined member 522 is disposed to face the inclined surface of the inclined member 513, and a rail engaging with the engagement member of the inclined member 513 is disposed on this inclined surface.

The base member 523 is made of, for example, a plate-shaped metal member, and an engagement member engaged with the rail disposed on the bottom surface of the inclined member 522 is provided on a top surface thereof.

The moving unit 524 is disposed at a side of the inclined member 522, for example, and is configured to move this inclined member 522 in a horizontal direction (the Y-axis direction in the drawing).

In the elevating unit 520, the moving unit 524 moves the inclined member 522 in a certain direction (the positive Y-axis direction in the drawing), thus allowing the inclined member 522 to press the inclined member 513 of the second holder 500 upwards. Thus, the elevating unit 520 can move the second holder 500 upwards.

Further, in the elevating unit 520, the moving unit 524 moves the inclined member 522 in a direction (the negative Y-axis direction in the drawing) opposite to the certain direction, so that the pressing of the inclined member 513 by the inclined member 522 is released. Thus, the elevating unit 520 can move the second holder 500 downwards.

As illustrated in FIG. 9 and FIG. 10, the second holder 500 is provided with the second imaging unit 530 and an inclination measuring unit 540.

The second imaging unit 530 is provided at a side portion of the base member 510, for example, and images the bonding surface W1j (see FIG. 3) of the upper wafer W1 held by the upper chuck 230. The second imaging unit 530 is provided with a macro-camera (not shown) having a low image magnification and a wide field of view and a micro-camera (not shown) having a high image magnification and a narrow field of view.

The inclination measuring unit 540 is configured to measure the inclination (degree of inclination) of a portion of the second holder 500 where the inclination measuring unit 540 is provided. The inclination measuring unit 540 has, for example, position measuring devices 541 to 543 provided under a bottom surface of the base member 510.

The position measuring devices 541 to 543 are, for example, non-contact type position measuring devices. The position measuring device 541 is configured to measure a height position of the bottom surface of the base member 510 positioned on the positive X-axis side of the lower chuck 231 when viewed from the top. The position measuring device 542 is configured to measure a height position of the bottom surface of the base member 510 positioned on the negative X-axis side of the lower chuck 231 when viewed from the top.

The position measuring device 543 is configured to measure a height position of the bottom surface of the base member 510 positioned on the positive Y-axis side of the lower chuck 231 when viewed from the top. For example, the position measuring devices 541 to 543 are equi-spaced from the center of the lower wafer W2 when viewed from the top.

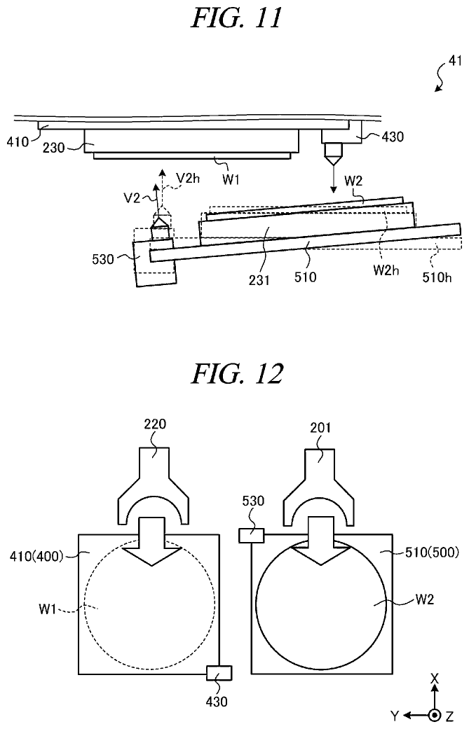

Details of a deviation amount calculating processing using this inclination measuring unit 540 will be described with reference to FIG. 11. FIG. 11 is a diagram for explaining a deviation amount calculating processing according to the exemplary embodiment. As described so far, the second holder 500 according to the exemplary embodiment is moved horizontally, elevated up and down, and rotated.

For this reason, in the bonding apparatus 41, the top surfaces of the lower chuck 231 and the base member 510 may be inclined with respect to the bottom surface of the upper chuck 230 rather than being parallel thereto, as shown in FIG. 11. Further, in FIG. 11, a case where the top surfaces of the lower chuck 231 and the base member 510 are parallel to the bottom surface of the upper chuck 230 is also illustrated by a dashed line.

If the first imaging unit 430 operates while considering the inclined lower wafer W2 as a parallel lower wafer W2h, a recognized position of the lower wafer W2 by the first imaging unit 430 is deviated from an actual position of the lower wafer W2.

Accordingly, when the first imaging unit 430 operates while considering the inclined lower wafer W2 as the parallel lower wafer W2h, a recognized position of a second alignment mark (not shown) formed at the lower wafer W2 may be deviated from an actual position thereof.

That is, if the top surfaces of the lower chuck 231 and the base member 510 are inclined, the recognized position of the lower wafer W2 may be deviated from the actual position of the lower wafer W2, so that alignment accuracy between the upper wafer W1 and the lower wafer W2 is reduced.

Likewise, when the second imaging unit 530 operates while considering the inclined base member 510 as a parallel base member 510h, a recognized position of the upper wafer W1 by the second imaging unit 530 may be deviated from an actual position of the upper wafer W1.

It is because, as shown in FIG. 11, a field of view V2 of the second imaging unit 530 mounted to the inclined base member 510 is deviated from a field of view V2h of the second imaging unit 530 mounted to the parallel base member 510h.

For this reason, when the second imaging unit 530 considers the inclined base member 510 as the parallel base member 510h, a recognized position of a first alignment mark (not shown) formed at the upper wafer W1 may be deviated from an actual position.

That is, if the top surfaces of the lower chuck 231 and the base member 510 are inclined, the recognized position of the upper wafer W1 is deviated from the actual position of the upper wafer W1, which results in the reduction in the alignment accuracy between the upper wafer W1 and the lower wafer W2.

In view of the foregoing, in the present exemplary embodiment, the controller 5 (see FIG. 1) measures the degree of inclination of the second holder 500 by using the inclination measuring unit 540 (see FIG. 9). Specifically, the controller 5 measures the degree of inclination (so-called roll) of the base member 510 in the X-axis direction by comparing the height position of the position measuring device 541 (see FIG. 9) and the height position of the position measuring device 542 (see FIG. 9).

Further, the controller 5 measures the degree of inclination (so-called pitch) of the base member 510 in the Y-axis direction by comparing a height position at a midpoint between the position measuring device 541 and the position measuring device 542 with the height position of the position measuring device 543 (see FIG. 9).

Then, based on the degree of inclination of the second holder 500 obtained by the measurement results of the inclination measuring unit 540, the controller 5 calculates the deviation amount between the recognized position of the second alignment mark of the lower wafer W2 imaged by the first imaging unit 430 and the actual position thereof.

Likewise, based on the degree of inclination of the second holder 500 obtained by the measurement results of the inclination measuring unit 540, the controller calculates the deviation amount between the recognized position of the first alignment mark of the upper wafer W1 imaged by the second imaging unit 530 and the actual position thereof.

Then, the controller 5 performs the alignment processing for the upper wafer W1 and the lower wafer W2 based on the positions of the first alignment mark and the second alignment mark from which the deviation amounts are calculated. Thus, the bonding precision between the upper wafer W1 and the lower wafer W2 can be improved.

Further, the above exemplary embodiment has been described for the example where the degree of inclination of the second holder 500 is evaluated by the three position measuring devices 541 to 543 and the deviation amount between the recognized position and the actual position of the alignment mark is calculated based on these evaluation results. However, the present disclosure is not limited to this example.

For example, the degree of inclination of the second holder 500 may be evaluated by two position measuring devices, and the deviation amount between the recognized position and the actual position of the alignment mark may be calculated based on these evaluation results. Even in this configuration, the degree of inclination of the second holder 500 in one direction in which the two position measuring devices are arranged can be evaluated. Thus, as compared to a case where the degree of inclination of the second holder 500 is not evaluated, the bonding precision between the upper wafer W1 and the lower wafer W2 can be improved.

Meanwhile, by evaluating the degree of inclination of the second holder 500 with the three position measuring devices 541 to 543 as in the above-described exemplary embodiment, the roll and the pitch of the second holder 500 can be both evaluated. Therefore, the bonding precision between the upper wafer W1 and the lower wafer W2 can be further improved.

In addition, in the present disclosure, the degree of inclination of the second holder 500 may be evaluated by four or more position measuring devices, and the deviation amount between the recognized position and the actual position of the alignment mark may be calculated based on these evaluation results. In this configuration as well, since both the roll and the pitch of the second holder 500 can be evaluated, the bonding precision between the upper wafer W1 and the lower wafer W2 can be further bettered.

Further, in the present disclosure, the inclination measuring unit 540 is not limited to being composed of the plurality of position measuring devices. For example, the inclination measuring unit 540 may be composed of a level, an autocollimator, or the like. In this configuration as well, since the degree of inclination of the second holder 500 can be evaluated, the bonding precision between the upper wafer W1 and the lower wafer W2 can be improved.

Moreover, in the exemplary embodiment, the second holder 500 needs to include the base member 510, the ceiling plate 511, and the plurality of supports 512. With this configuration, since it is possible to suppress a stress from the elevating unit 520 from being directly applied to the base member 510, deformation of the base member 510 can be suppressed.

Therefore, according to the exemplary embodiment, since the degree of inclination of the base member 510 can be evaluated with high accuracy, the bonding precision between the upper wafer W1 and the lower wafer W2 can be further improved.

FIG. 12 to FIG. 17 are diagrams for explaining a sequence of the alignment processing according to the exemplary embodiment. As shown in FIG. 12, the controller 5 (see FIG. 1) first operates the inverting mechanism 220 to carry the upper wafer W1 to the first holder 400, and further operates the transfer mechanism 201 to carry the lower wafer W2 to the second holder 500.

In the example of FIG. 12 to FIG. 17, the first imaging unit 430 is disposed at a corner (lower right corner in the drawing) of the base member 410 when viewed from the top, and the second imaging unit 530 is disposed at a corner (upper left corner in the drawing) of the base member 510. Further, in the following drawings, illustration of the upper chuck 230 and the lower chuck 231 are omitted.

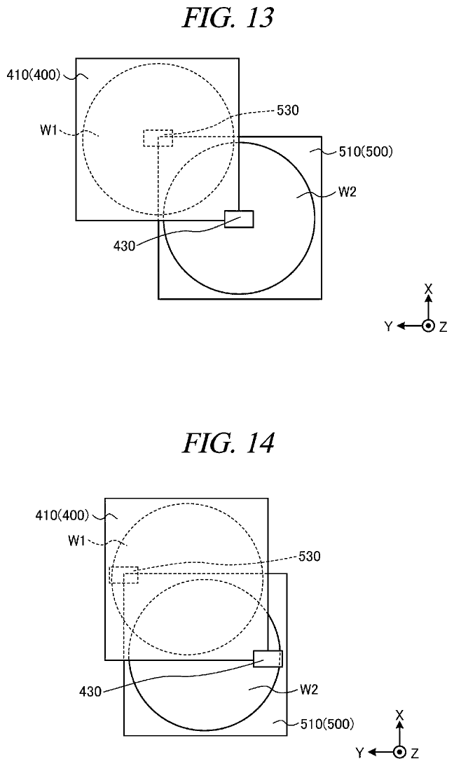

Next, as shown in FIG. 13, the controller 5 (see FIG. 1) checks the position of the second alignment mark located at the center of the lower wafer W2 with the macro-camera of the first imaging unit 430. In addition, the controller 5 checks the position of the first alignment mark located at the center of the upper wafer W1 with the macro-camera of the second imaging unit 530. In this way, the controller 5 investigates the positions of the upper wafer W1 and the lower wafer W2 in the rotational direction with rough precision.

Further, the process of FIG. 13 is performed in the state that the upper wafer W1 and the lower wafer W2 are spaced apart from each other at a distance of about 2 mm (that is, at a spaced position), for example. In addition, since the process of FIG. 13 is a process performed by the macro-camera with the rough precision, the above-described deviation amount calculating processing using the inclination measuring unit 540 does not need to be performed.

Then, as shown in FIG. 14, the controller 5 (see FIG. 1) checks the position of the second alignment mark located at the periphery of one side (right side in the drawing) of the lower wafer W2 with the micro-camera of the first imaging unit 430. Also, the controller 5 checks the position of the first alignment mark located at the periphery of one side (left side in the drawing) of the upper wafer W1 with the micro-camera of the second imaging unit 530.

Further, although not shown in FIG. 14, the controller 5 checks the position of the second alignment mark located at the periphery of the other side (left side in the drawing) of the lower wafer W2 with the micro-camera of the first imaging unit 430. Also, the controller 5 checks the position of the first alignment mark located at the periphery of the other side (right side in the drawing) of the upper wafer W1 with the micro-camera of the second imaging unit 530.

In this way, the controller 5 investigates the positions of the upper wafer W1 and the lower wafer W2 in the rotational direction with high precision. Then, the controller 5 rotates the lower wafer W2 based on the obtained result to align the position of the lower wafer W2 in the rotational direction to that of the upper wafer W1.

Here, in the exemplary embodiment, by performing the above-described deviation amount calculating processing using the inclination measuring unit 540, the deviation amounts between the recognized positions and the actual positions of the first alignment mark and the second alignment mark are respectively calculated. Accordingly, the position of the lower wafer W2 in the rotational direction can be accurately aligned to that of the upper wafer W1.

The process of FIG. 14 is performed in the state that the upper wafer W1 and the lower wafer W2 are spaced apart from each other at the distance of about 2 mm (that is, at the spaced position), for example.

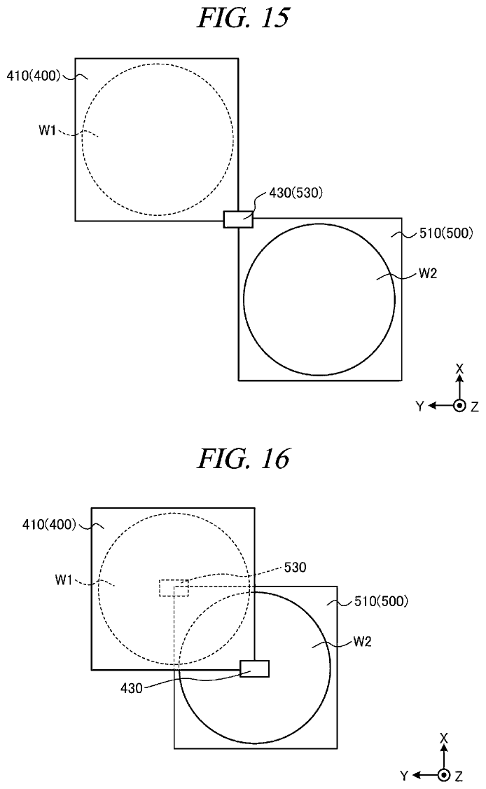

Next, as illustrated in FIG. 15, the controller 5 (see FIG. 1) places the micro-camera of the first imaging unit 430 and the micro-camera of the second imaging unit 530 at the same position when viewed from the top. Then, the controller 5 aligns the origin of the micro-camera of the first imaging unit 430 with the origin of the micro-camera of the second imaging unit 530.

Here, in the exemplary embodiment, by performing the above-described deviation amount calculating processing using the inclination measuring unit 540, the deviation amounts between the recognized positions and the actual positions of the pair of cameras are respectively calculated. Accordingly, the origin of the micro-camera of the first imaging unit 430 and the origin of the micro-camera of the second imaging unit 530 can be aligned with high precision.

Further, the process of FIG. 15 is performed in the state that the upper wafer W1 and the lower wafer W2 are spaced apart from each other at a distance of about 4.5 mm (that is, at a further spaced position), for example.

Thereafter, as shown in FIG. 16, the controller 5 (see FIG. 1) checks the position of the second alignment mark located at the center of the lower wafer W2 with the micro-camera of the first imaging unit 430. In addition, the controller 5 checks the position of the first alignment mark located at the center of the upper wafer W1 with the micro-camera of the second imaging unit 530. In this way, the controller 5 investigates the center position of the upper wafer W1 and the center position of the lower wafer W2.

Here, in the exemplary embodiment, by performing the above-described deviation amount calculating processing using the inclination measuring unit 540, the deviation amounts between the recognized center positions and the actual center positions of the upper wafer W1 and the lower wafer W2 are respectively calculated. Accordingly, the center position of the upper wafer W1 and the center position of the lower wafer W2 can be investigated with high precision.

The process of FIG. 16 is performed in the state that the upper wafer W1 and the lower wafer W2 are spaced apart from each other at the distance of about 2 mm (that is, at the spaced position), for example.

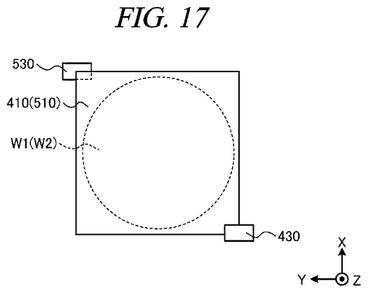

Subsequently, based on the center position of the upper wafer W1 and the center position of the lower wafer W2 obtained in the process of FIG. 16, the controller 5 (see FIG. 1) aligns the center positions of the upper wafer W1 and the lower wafer W2 when viewed from the top, as illustrated in FIG. 17.

Further, the controller 5 brings the lower wafer W2 whose center position is aligned with the center position of the upper wafer W1 close to the upper wafer W1 to a predetermined distance (e.g., 80 μm to 100 μm). That is, the controller 5 moves the lower wafer W2 to a proximate position, thus completing the series of processes of the alignment processing.

The bonding apparatus 41 according to the exemplary embodiment includes the first holder 400, the second holder 500, the horizontally moving unit 316, the elevating unit 520, the inclination measuring unit 540, and the controller 5. The first holder 400 attracts and holds the first substrate (upper wafer W1) on the bottom surface thereof. The second holder 500 is disposed under the first holder 400, and attracts and holds, on the top surface thereof, the second substrate (lower wafer W2) to be bonded to the first substrate (upper wafer W1). The horizontally moving unit 316 moves the first substrate (upper wafer W1) and the second substrate (lower wafer W2) relative to each other in the horizontal direction. The elevating unit 520 moves the second substrate (lower wafer W2) up and down between the proximate position close to the first substrate (upper wafer W1) and the spaced position farther from the first substrate (upper wafer W1) than the proximate position. The inclination measuring unit 540 measures the inclination of the second holder 500. The controller 5 controls the individual components. Further, the controller 5 calculates the position of the second substrate (lower wafer W2) in the horizontal direction based on the measurement result of the inclination measuring unit 540. Thus, the bonding precision between the upper wafer W1 and the lower wafer W2 can be improved.

Further, the bonding apparatus 41 according to the exemplary embodiment further includes the first imaging unit 430 provided at the first holder 400 and configured to image the second alignment mark formed at the second substrate (lower wafer W2). Furthermore, the controller 5 calculates, based on the measurement result of the inclination measuring unit 540, the deviation amount between the recognized position of the second alignment mark imaged by the first imaging unit 430 and the actual position thereof. Thus, the bonding precision between the upper wafer W1 and the lower wafer W2 can be improved.

Moreover, in the bonding apparatus 41 according to the exemplary embodiment, the controller 5 calculates the position of the first substrate (upper wafer W1) in the horizontal direction based on the measurement result of the inclination measuring unit 540. Thus, the bonding precision between the upper wafer W1 and the lower wafer W2 can be improved.

In addition, the bonding apparatus 41 according to the exemplary embodiment further includes the second imaging unit 530 provided at the second holder 500 and configured to image the first alignment mark formed at the first substrate (upper wafer W1). Further, the controller calculates, based on the measurement result of the inclination measuring unit 540, the deviation amount between the recognized position of the first alignment mark imaged by the second imaging unit 530 and the actual position thereof. Thus, the bonding precision between the upper wafer W1 and the lower wafer W2 can be improved.

Besides, in the bonding apparatus 41 according to the exemplary embodiment, the inclination measuring unit 540 measures the inclination of the second holder 500 by measuring the height position of the second holder 500 at three or more points. Therefore, the bonding precision between the upper wafer W1 and the lower wafer W2 can be further improved.

In the bonding apparatus 41 according to the embodiment, the second holder 500 includes a base member 510, a ceiling plate 511, and multiple supports 512. The inclination of the base member 510 is measured by the inclination measuring unit 540. The ceiling plate 511 is disposed below the base member 510. The multiple supports 512 are provided between the base member 510 and the ceiling plate 511. Accordingly, the bonding precision between the upper wafer W1 and the lower wafer W2 can be further improved.

Further, a bonding method according to the exemplary embodiment includes a process (process S105) of holding the first substrate, a process (process S109) of holding the second substrate, a process (process S110) of performing the alignment, and a process (process S112) of performing the bonding. In the process (process S105) of holding the first substrate (upper wafer W1), the attracting pressure is generated in the bottom surface of the first holder 400 to hold the first substrate (upper wafer W1). In the process (process S109) of holding the second substrate, the attracting pressure is generated in the top surface of the second holder 500, which is disposed under the first holder 400, to hold the second substrate (lower wafer W2). In the process (process S110) of performing the alignment, the first substrate (upper wafer W1) and the second substrate (lower wafer W2) are aligned relative to each other in the horizontal direction. In the process (process S112) of performing the bonding, the first substrate (upper wafer W1) and the second substrate (lower wafer W2) are bonded to each other. Further, in the process (process S110) of performing the alignment, the position of the second substrate (lower wafer W2) in the horizontal direction is calculated based on the measurement result of the inclination measuring unit 540 configured to measure the inclination of the second holder 500. Thus, the bonding precision between the upper wafer W1 and the lower wafer W2 can be improved.

So far, the exemplary embodiments of the present disclosure have been described. However, the present disclosure is not limited to the exemplary embodiments, and various changes and modifications may be made without departing from the spirit of the present disclosure.

The exemplary embodiments disclosed herein are illustrative in all aspects and do not limit the present disclosure. Indeed, the above-described exemplary embodiments may be implemented in various forms. Further, the above-described exemplary embodiments may be omitted, replaced and modified in various ways without departing from the scope and the spirit of the appended claims.

According to the present disclosure, it is possible to improve the bonding precision between the substrates.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A bonding apparatus, comprising:
a first holder configured to attract and hold a first substrate on a bottom surface thereof;
a second holder disposed under the first holder and configured to attract and hold, on a top surface thereof, a second substrate to be bonded to the first substrate;
a horizontally moving unit configured to move the first substrate and the second substrate relative to each other in a horizontal direction;
an elevating unit configured to move the second substrate up and down between a proximate position close to the first substrate and a spaced position farther from the first substrate than the proximate position;
an inclination measuring unit configured to measure an inclination of the second holder; and
a controller configured to control the first holder, the second holder, the horizontally moving unit, the elevating unit and the inclination measuring unit,
wherein the controller calculates a position of the second substrate in the horizontal direction based on a measurement result of the inclination measuring unit.

2. The bonding apparatus of claim 1, further comprising:
a first imaging unit provided at the first holder and configured to image a second alignment mark formed at the second substrate,
wherein the controller calculates, based on the measurement result of the inclination measuring unit, a deviation amount between a recognized position of the second alignment mark imaged by the first imaging unit and an actual position thereof.

3. The bonding apparatus of claim 1,
wherein the controller calculates a position of the first substrate in the horizontal direction based on the measurement result of the inclination measuring unit.

4. The bonding apparatus of claim 3, further comprising:
a second imaging unit provided at the second holder and configured to image a first alignment mark formed at the first substrate,
wherein the controller calculates, based on the measurement result of the inclination measuring unit, a deviation amount between a recognized position of the first alignment mark imaged by the second imaging unit and an actual position thereof.

5. The bonding apparatus of claim 1,
wherein the inclination measuring unit measures the inclination of the second holder by measuring a height position of the second holder at three or more points.

6. The bonding apparatus of claim 1,
wherein the second holder comprises:
a base member whose inclination is measured by the inclination measuring unit;
a ceiling plate disposed under the base member; and
multiple supports provided between the base member and the ceiling plate.

7. A bonding method, comprising:
holding a first substrate by generating an attracting pressure in a bottom surface of a first holder;
holding a second substrate by generating an attracting pressure in a top surface of a second holder disposed under the first holder;
aligning the first substrate and the second substrate relative to each other in a horizontal direction; and
bonding the first substrate and the second substrate,
wherein in the aligning of the first substrate and the second substrate, a position of the second substrate in the horizontal direction is calculated based on a measurement result of an inclination measuring unit configured to measure an inclination of the second holder.
